(19) United States
(12) Patent Application Publication
(10) Pub. No.: US 2010/0003779 A1
(43) Pub. Date: Jan. 7, 2010

(54) METHOD OF PRODUCING SOLID-STATE IMAGING DEVICE

(75) Inventor: Manjirou Watanabe, Minami-Ashigara-shi (JP)

Correspondence Address: BIRCH STEWART KOLASCH & BIRCH, PO BOX 747, FALLS CHURCH, VA, 22040-0747, US

(73) Assignee: FUJIFILM Corporation, Tokyo (JP)

(21) Appl. No.: 12/521,172

(22) PCT Filed: Dec. 19, 2007
(86) PCT No.: PCT/JP2007/075045

§ 371 Date: Jul. 16, 2009

(30) Foreign Application Priority Data
Dec. 28, 2006 (JP) 2006-355824

(51) Int. Cl. H01L 21/50

(52) U.S. Cl. 438/64; 257/E21.499

(57) ABSTRACT

A method of producing a solid-state imaging device according to one embodiment of the present invention is characterized in that, in a method of producing a solid-state imaging device such that a solid-state imaging element wafer is bonded to a light transmissive substrate on one surface of which spacers are formed so as to surround solid-state imaging elements formed on the solid-state imaging element wafer and ditches are formed between the spacers to produce a bonded substrate and then the bonded substrate is divided correspondingly to the individual solid-state imaging elements, a support is bonded to the surface opposite to the surface of the light transmissive substrate on which the ditches are formed.

### TECHNICAL FIELD

The present invention relates to a method of producing a solid-state imaging device, and in particular, to a method of producing a solid-state imaging device produced by bonding a solid-state imaging element wafer to a light transmissive substrate.

### BACKGROUND ART

In recent years, a solid-state imaging device formed of a charge coupled device (CCD) or a complementary metal oxide semiconductor (CMOS) used in a digital camera or a cellular phone has been required to be further downsized and mass produced.

To downsize and mass produce a solid-state imaging device based on such a requirement, there is proposed a solid-state imaging device produced such that a solid-state imaging element wafer on which the light receiving units of a large number of solid-state imaging devices are formed is bonded to a light transmissive substrate through spacers formed correspondingly with the position surrounding each light receiving unit or a sealing material, thereafter the solid-state imaging element wafer bonded to the light transmissive substrate is subject to processes such as the formation of through wirings, dicing and others, and a method of producing the solid-state imaging device (refer to Patent Documents 1 and 2, for example).

In such a method of producing the solid-state imaging device, in the dicing process, in particular, there is a problem in that the solid-state imaging element wafer is damaged by fragments of the light transmissive substrate caused at the time of dicing because the distance between gaps formed between the light transmissive substrate and the solid-state imaging element wafer is narrow. To solve the problem, a method of producing a solid-state imaging device is proposed in which ditches are formed between spacers formed on the light transmissive substrate bonded to the solid-state imaging element wafer, the light transmissive substrate on which the ditches are formed is bonded to the solid-state imaging element wafer and then dicing is performed (refer to Patent Document 3 for example).

Forming the ditches widens the gap between the light transmissive substrate and the solid-state imaging element wafer and easily ejects fragments of the light transmissive substrate at the time of dicing, which reduces damage to the solid-state imaging element wafer.

Patent Document 1: Japanese Patent Application Laid-Open No. 2001-351997

Patent Document 2: Japanese Patent Application Laid-Open No. 2004-88082

Patent Document 3: Japanese Patent Application Laid-Open No. 2006-100587

On the other hand, in the situation where mass production has been required in recent years, the solid-state imaging element wafer has increased in size year by year and at the same time the light transmissive substrate bonded thereto has increased in diameter. For this reason, the light transmissive substrate in which ditches are provided between the spacers does not ensure a sufficient stiffness, which causes a problems in that the light transmissive substrate is curved to worsen in flatness at the time of bonding, bent at the time of transportation, due to which the light transmissive substrate cannot be handled or is damaged.

The present invention has been made in view of the above problems, and has for its object to provide a method of producing the solid-state imaging device which increases the stiffness of the light transmissive substrate, prevents the light transmissive substrate from being curved to improve transportability and keeps clean the surface of the light transmissive substrate.

### DISCLOSURE OF THE INVENTION

To achieve the object, a method of producing a solid-state imaging device according to a first aspect of the present invention is characterized in that, in a method of producing a solid-state imaging device such that a solid-state imaging element wafer is bonded to a light transmissive substrate on one surface of which spacers are formed so as to surround solid-state imaging elements formed on the solid-state imaging element wafer and ditches are formed between the spacers to produce a bonded substrate and then the bonded substrate is divided correspondingly to the individual solid-state imaging elements, a support is bonded to the surface opposite to the surface of the light transmissive substrate on which the ditches are formed.

According to the first aspect, the light transmissive substrate on one surface of which the spacers are formed correspondingly to the position of the solid-state imaging elements formed on the solid-state imaging element wafer to surround the solid-state imaging elements is diced by half-cut dicing with a dicing device between the spacers to form ditches.

The support which prevents the light transmissive substrate from being curved or damaged due to its insufficient stiffness is bonded to the surface opposite to the surface of the light transmissive substrate on which the ditches are formed and the spacers are provided.

This increases the stiffness of the light transmissive substrate to prevent the light transmissive substrate from being curved, improves flatness at the time of bonding the light transmissive substrate to the solid-state imaging element wafer and facilitates transportation to reduce risk of damage.

The second aspect of the present invention is characterized in that, in the first aspect, the support is bonded to the light transmissive substrate by a self-peeling double-face tape of which at least one face is self-peeled by heating or radiating with ultraviolet rays.

According to the second aspect, the support is bonded to the light transmissive substrate by a self-peeling double-face tape of which at least one face has a self-peeling property. The self-peeling double-face tape has the property that at least one face thereof loses an adhesive force by external energy such as heating or ultraviolet rays to generate a self-peeling force.

This finishes transportation and bonding with the solid-state imaging element wafer to enable the unnecessary support to be easily peeled without damaging the light transmissive substrate.

The third aspect of the present invention is characterized in that, in the first or the second aspect, the protective tape which protects the surface of the light transmissive substrate is stuck on the surface opposite to the surface of the light transmissive substrate on which the ditches are formed and the self-peeling double-face tape is stuck on the protective tape.

According to the third aspect, the protective tape which protects the surface of the light transmissive substrate, of which the adhesive portion is designed so that an adhesive residue can be very little is stuck on the surface opposite to the surface of the light transmissive substrate to which the support is bonded and on which the ditches are formed, and the self-peeling double-face tape is stuck on the protective tape to join the light transmissive substrate.

This keeps clean the surface of the light transmissive substrate because a contaminating substance such as an adhesive residue is little left on the light transmissive substrate even if the self-peeling tape and the protective tape are peeled after the light transmissive substrate has been peeled.

The fourth aspect of the present invention is characterized in that, in any of the first to the third aspect, the support is a sheet material formed of glass, resin or metal.

According to the fourth aspect, the sheet material formed of glass, resin or metal which is either transparent or low in thermal insulation is used as the support. This enables facilitating handling and easily increasing the stiffness of the light transmissive substrate, prevents the light transmissive substrate from being curved and improves transportability.

The fifth aspect of the present invention is characterized in that, in any of the first to the fourth aspect, the support is formed of a sheet material with light transmissivity in the case where the self-peeling double-face tape is self-peeled by ultraviolet rays.

According to the fifth aspect, the support is formed of glass or transparent resin to transmit ultraviolet rays. Thereby, irradiating the support with ultraviolet rays subjects the self-peeling double-face tape to ultraviolet rays to start the self-peeling in the case where the self-peeling double-face tape is self-peeled by ultraviolet rays.

The sixth aspect of the present invention is characterized in that, in any of the first to the fifth aspect, in the case where the self-peeling double-face tape is heated to be self-peeled, the self-peeling double-face tape is heated at a temperature lower than a temperature at which the spacer is peeled from the solid-state imaging element wafer or the light transmissive substrate or the spacer is fractured due to a warp caused by difference in thermal expansion coefficient between the solid-state imaging element wafer and the light transmissive substrate.

According to the sixth aspect, the self-peeling double-face tape having the property that it peels at a low temperature of about 90° C. is used in the case where the self-peeling double-face tape is heated to be self-peeled. This prevents peeling and fracturing caused by warp of the bonded substrate due to difference in thermal expansion coefficient between the light transmissive substrate and the solid-state imaging element wafer.

The seven aspect of the present invention is characterized in that, in any of the first to the sixth aspect, an opening through which the solid-state imaging element wafer can be imaged is provided in the self-peeling double-face tape and the protective tape.

According to the seventh aspect, the opening for imaging a mark formed to perform location on the solid-state imaging element wafer at the time of bonding the support to the light transmissive substrate is provided in advance in the self-peeling double-face tape and the protective tape.

This enables easy location when the light transmissive substrate is bonded to the solid-state imaging element wafer after the support has been bonded to the light transmissive substrate.

As described above, according to the method of producing solid-state imaging device of the present invention, the support increases the stiffness of the light transmissive substrate to prevent the light transmissive substrate from being bent, improve transportability and prevent damage. In addition, the protective tape keeps clean the surface of the light transmissive substrate.

### BRIEF DESCRIPTION OF THE DRAWINGS

FIG. 1 is a perspective view of a solid-state imaging device according to the embodiment of the present invention;

FIG. 2 is a cross section of the solid-state imaging device according to the embodiment of the present invention;

FIG. 3 is a flow chart showing the steps of a method of producing the solid-state imaging device;

FIGS. 4A to 4H are side views describing the steps of the method of producing the solid-state imaging device;

FIG. 5 is a flow chart showing the steps of a method of producing the solid-state imaging device according to another embodiment of the present invention;

FIGS. 6A to 6I are side views describing the steps of a method of producing the solid-state imaging device according to another embodiment of the present invention;

FIGS. 7A to 7G are side views describing the steps of a method of producing the solid-state imaging device which uses another protective tape; and

FIG. 8 is a side view illustrating an opening.

### DESCRIPTION OF SYMBOLS

1 . . . Solid-state imaging device
2 . . . Solid-state imaging element chip
3 . . . Solid-state imaging element
4 . . . Cover glass
5 . . . Spacer
6 . . . Pad
10 . . . Light transmissive substrate
11 . . . Ditch
12 . . . Support
13 . . . Self-peeling double-face tape
14 & 18 . . . Protective tape
15 . . . Porous chuck table
16 . . . Opening
20 . . . Solid-state imaging element wafer

### BEST MODE FOR CARRYING OUT THE INVENTION

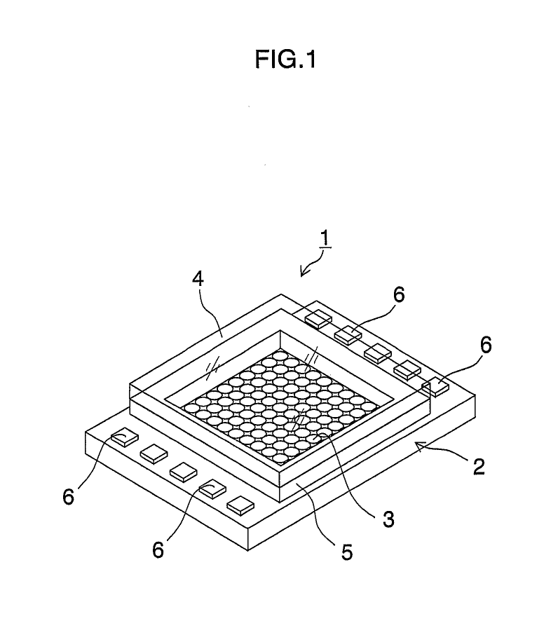

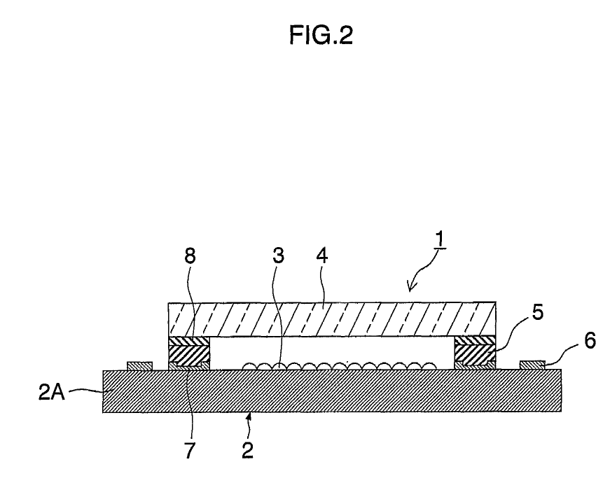

A preferable embodiment of a method of producing a solid-state imaging device according to the present invention is described below with reference to the accompanied drawings. FIGS. 1 and 2 are a perspective view and a cross section illustrating the external appearance of the solid-state imaging device according to the present invention.

The solid-state imaging device 1 includes a solid-state imaging element chip 2 on which solid-state imaging elements 3 are provided, a spacer 5 which is fixed to the solid-state imaging element chip 2 and surrounds the solid-state imaging elements 3 and a cover glass 4 which is fixed over the spacer 5 and seals the solid-state imaging elements 3.

The solid-state imaging element chip 2 is made through the process that a solid-state imaging element wafer described later is divided. Similarly the cover glass 4 is made through the process that a light transmissive substrate described later is divided.

As illustrated in FIG. 2, the solid-state imaging element chip 2 includes a rectangular chip substrate 2A, the solid-state imaging elements 3 formed on the chip substrate 2A and a plurality of pads (electrodes) 6 which is arranged outside the solid-state imaging elements 3 and used for external wiring. The chip substrate 2A is made of, for example, silicon single crystal and is approximately 300 μm in thickness.

The solid-state imaging element 3 is produced in an ordinary semiconductor device production process. The solid-state imaging element 3 includes a photo diode which is a photo acceptance unit formed on a wafer (the solid-state imaging element chip 2), a transfer electrode which transfers excited voltage outside, a light shielding film with an opening and an interlayer insulating film. The solid-state imaging element 3 is configured such that an inner lens is formed over the interlayer insulating film, a color filter is provided over the inner lens through an intermediate layer and a micro lens is provided over the color filter through an intermediate layer.

The above configuration of the solid-state imaging element 3 causes the micro lens and the inner lens to focus light incident from the outside onto the photo diode to increase an effective aperture ratio.

The cover glass 4 uses a transparent glass which is comparable in thermal expansion coefficient to silicon, for example, Pyrex (registered trademark) glass and is approximately 500 μm in thickness for example.

The spacer 5 uses inorganic materials, for example, polycrystalline silicon because the spacer 5 is desirably similar to the chip substrate 2A and the cover glass 4 in properties such as thermal expansion coefficient and others. When a cross section of part of the frame-shaped spacer 5 is viewed, the cross section is approximately 200 μm in width and 100 μm in thickness, for example. One end face of the spacer 5 is bonded to the chip substrate 2A using an adhesive 7 and the other end face thereof is bonded to the cover glass 4 using an adhesive 8.

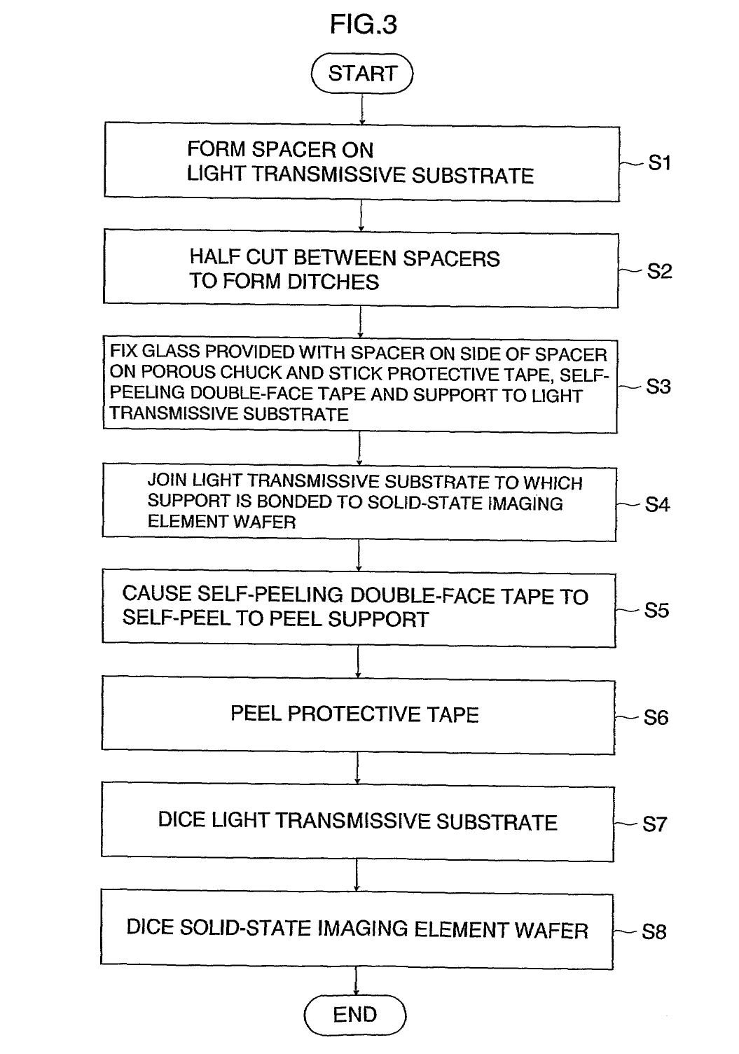

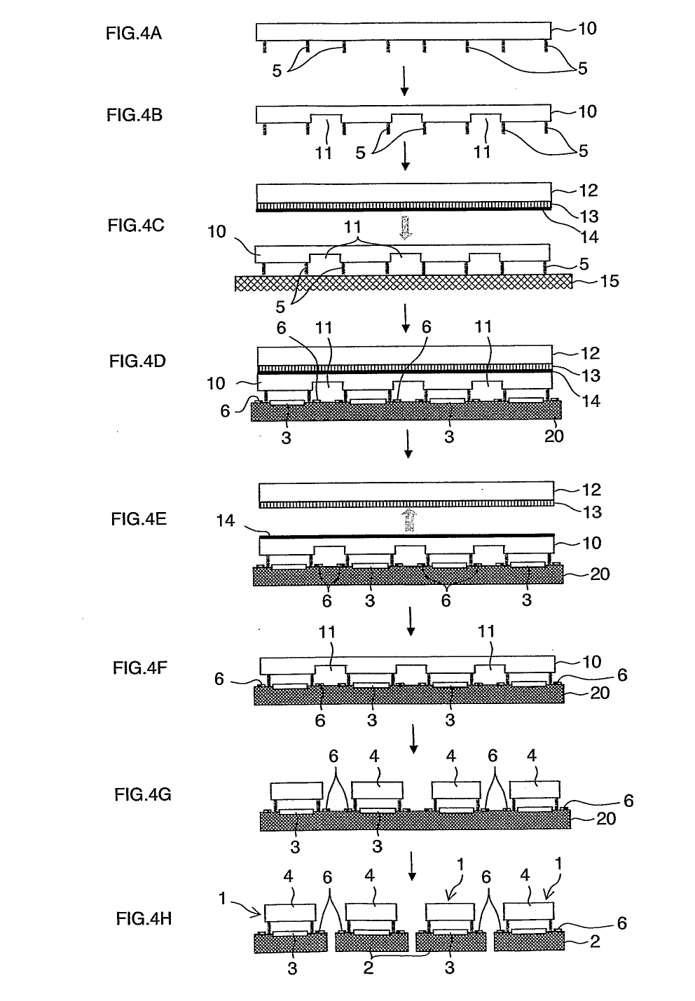

A method of producing the solid-state imaging device according to the present invention is described below. FIG. 3 is a flow chart showing the steps of a method of producing the solid-state imaging device according to the present invention. FIGS. 4A to 4H are side views describing the steps of the method of producing the same.

As illustrated in FIG. 4A, in the method of producing the solid-state imaging device according to the present invention, the spacer 5 is formed on a light transmissive substrate 10 such that the spacer 5 corresponds to a position of the solid-state imaging element formed on the solid-state imaging element wafer described hereunder (step S1).

The light transmissive substrate 10 uses a glass wafer which is transparent and translucent, does not block off light such as ultraviolet rays used at the following steps and is almost comparable in linear expansion coefficient to the solid-state imaging element wafer. For example, Pyrex (registered trademark) glass with a linear thermal expansion coefficient of 3 ppm/° C. or more to 4 ppm/° C. or less can be preferably used as the light transmissive substrate 10.

The spacer 5 is formed in such a manner that a silicon substrate stuck on the light transmissive substrate is etched by etching method using photolithography or one being formed into the shape of the spacer 5 in advance is adhered to the light transmissive substrate 10.

As illustrated in FIG. 4B, the light transmissive substrate 10 is diced by half-cut dicing with a dicing device between the spacers 5 on the surface of the light transmissive substrate 10 on which the spacers 5 are formed, thereby forming ditches 11 (step S2).

In the half-cut dicing, when a 500 μm thick light transmissive substrate 10 is used for example, the ditch 11 with a width of approximately 900 μm and a depth of approximately 300 μm is formed. When a 300 μm thick light transmissive substrate 10 is used, the ditch 11 with a depth of approximately 150 μm is formed.

As illustrated in FIG. 4C, the light transmissive substrate 10 on which the spacers 5 are formed is sucked and fixed on a porous chuck table 15 on the side of the spacer 5. A protective tape 14, a self-peeling double-face tape 13 and a support 12 are bonded in this order to the light transmissive substrate 10 sucked and fixed on the table (step S3).

An adhesive portion is formed on one face of the protective tape 14. The adhesive portion is stuck on the surface opposite to the surface of the light transmissive substrate 10 on which the ditches are formed. A low-contamination tape, is used as the protective tape 14, of which the adhesive portion is designed so that an adhesive residue on the component to which the protective tape 14 is stuck can be very little after the protective tape 14 is peeled. For example, a back grinding protective tape “ELEP HOLDER” (registered trademark) produced by Nitto Denko Corporation may be preferably used.

The self-peeling double-face tape 13 has the property that at least one face of the adhesive faces formed on both faces thereof loses an adhesive force by external energy such as heating or ultraviolet rays and generates a self-peeling force. For example, “SELFA” produced by Sekisui Chemical Co., Ltd. and “RIBA-ALPHA” produced by Nitto Denko Corporation may be preferably used. The one face of the self-peeling double-face tape 13 which has the self-peeling property is stuck on the substrate surface of the protective tape 14 and the other normal adhesive surface is stuck on the support 12.

The support 12 is a sheet material formed of glass, resin or metal which is preferably comparable in linear expansion coefficient to the light transmissive substrate 10 and superior in flatness. When ultraviolet rays are used to self-peel the self-peeling double-face tape 13, the support 12 is a transparent or translucent light-transmissive material to transmit ultraviolet rays. When the support 12 is heated to self-peel the tape 13, a material which is low in thermal insulation is selected.

It is preferable to join the protective tape 14, the self-peeling double-face tape 13 and the support 12 to the light transmissive substrate 10 over the porous chuck table 15 which is superior in flatness and produces a sucking force over the entire surface to avoid the damage of the light transmissive substrate 10, using a rubber roller so that bubbles do not enter at the time of bonding under a vacuum environment.

In this way, the protective tape 14, the self-peeling double-face tape 13 and the support 12 are bonded to the light transmissive substrate 10 to increase the stiffness of the light transmissive substrate 10, prevent curvature, improve transportability and avoid damage. The protective tape 14 keeps clean the surface of the light transmissive substrate 10.

In the solid-state imaging device 1, if it does not matter if the surface of the light transmissive substrate 10 is somewhat contaminated, the solid-state imaging device 1 can be preferably embodied even if the protective tape 14 is not stuck.

As illustrated in FIG. 4D, the light transmissive substrate 10, to which the support 12 is bonded, is bonded to the solid-state imaging element wafer 20 (step S4).

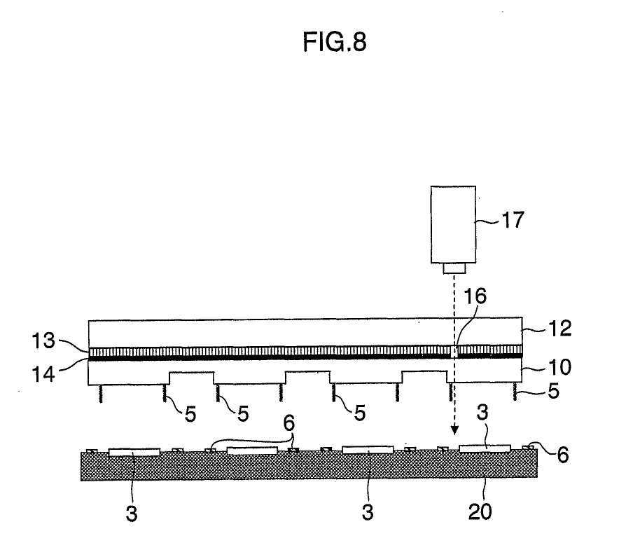

When the light transmissive substrate 10 is bonded to the solid-state imaging element wafer 20, as illustrated in FIG. 8, a locating mark formed for location on the solid-state imaging element wafer 20 is imaged using an imaging device 17 through an opening portion 16 formed in advance in the protective tape 14 and the self-peeling double-face tape 13. This ensures an accurate location to join the light transmissive substrate 10 to the solid-state imaging element wafer 20 by adhesion, thereby producing a bonded substrate.

As illustrated in FIG. 4E, the support 12 bonded to the light transmissive substrate 10 is heated or irradiated with ultraviolet rays to self-peel the self-peeling double-face tape 13, resulting in peeling of the support 12 from the light transmissive substrate 10 (step S5).

When the self-peeling double-face tape 13 which is self-peeled by ultraviolet rays is used to peel the support 12, irradiating the support 12 with ultraviolet rays from the side of support 12 causes the surface of the self-peeling double-face tape 13 stuck on the protective tape 14 to produce a self-peeling property, resulting in peeling of the support 12 and the self-peeling double-face tape 13 from the light transmissive substrate 10. At this point, the support 12 is transparent or translucent and therefore transmits ultraviolet rays.

When the self-peeling double-face tape 13 which is self-peeled by heating is used, a temperature at which the self-peeling double-face tape 13 produces self-peeling property is set lower than a temperature at which the spacer 5 is broken. This setting is done to prevent the spacer 5 from being peeled or fractured due to a warp caused by difference in thermal expansion coefficient between the bonded solid-state imaging element wafer 20 and the light transmissive substrate 10 at the time of heating. Specifically, a setting temperature is preferably approximately 80° C. to 100° C.

As illustrated in FIG. 4F, the protective tape 14 is peeled from the light transmissive substrate 10 (step S6).

The protective tape 14 is peeled directly or after it has been irradiated with ultraviolet rays.

As illustrated in FIG. 4G, the light transmissive substrate 10 of the bonded substrate is diced into an individual cover glass 4 (step S7).

After the bonded light transmissive substrate 10 is diced, the solid-state imaging element wafer 20 is diced into an individual solid-state imaging element chip 2 to produce the solid-state imaging device 1 (step S8).

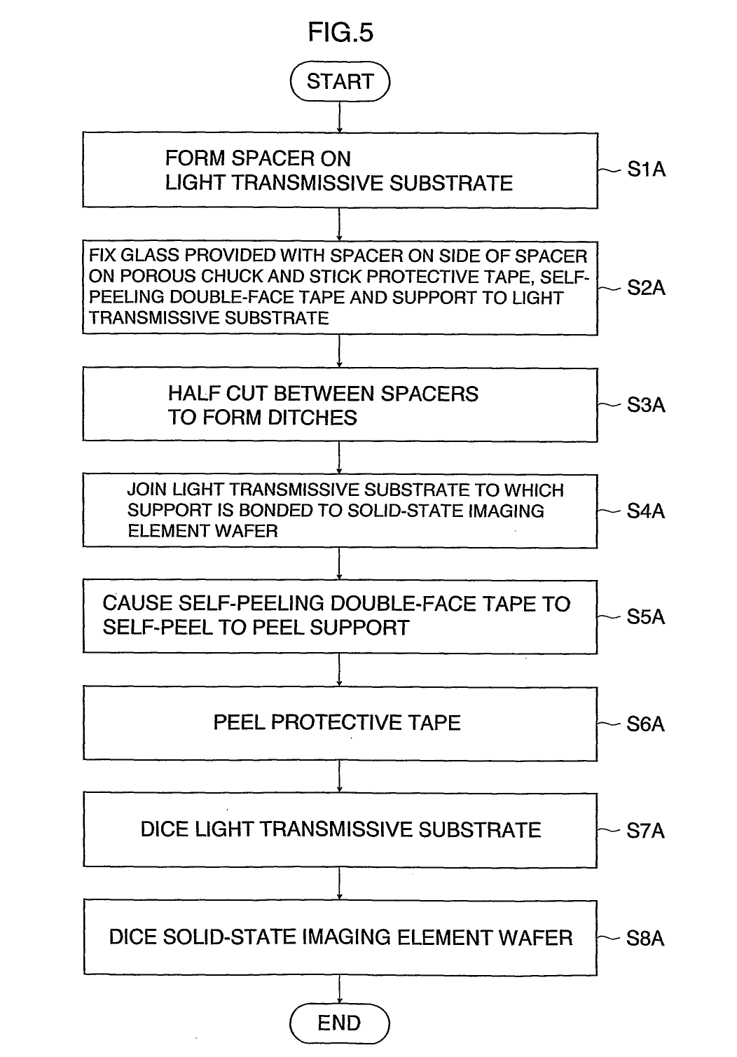

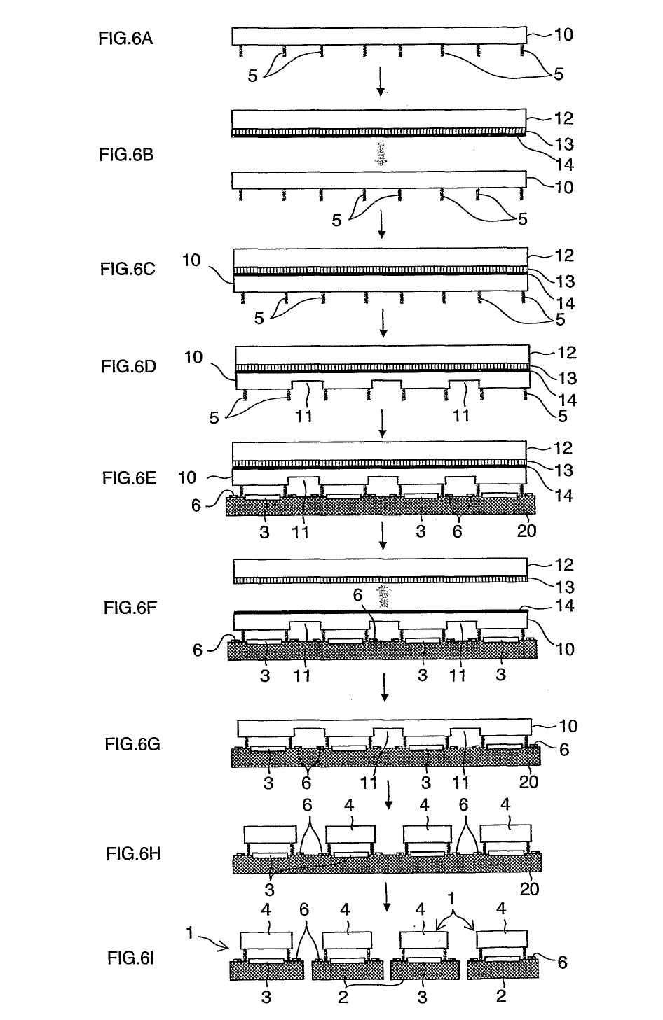

Another method of producing the solid-state imaging device according to the present invention is described below. FIG. 5 a flow chart showing the steps of another method of producing the solid-state imaging device according to the present invention. FIGS. 6A to 6I are side views describing the steps of another method of producing the solid-state imaging device. Incidentally, the component parts which are the same as those in the foregoing embodiment are given the same reference numbers and the description of the similar steps is omitted.

In another method of producing the solid-state imaging device according to the present invention, as illustrated in FIG. 6A, the spacer 5 is formed on the light transmissive substrate 10 such that the spacer corresponds to a position of the solid-state imaging element 3 formed on the solid-state imaging element wafer 20 (step S1A).

As illustrated in FIGS. 6B and 6C, the protective tape 14, the self-peeling double-face tape 13 and the support 12 are bonded in this order to the light transmissive substrate 10 (step S2A).

The light transmissive substrate 10 in which the ditches 11 have not yet formed maintains stiffness, so that it does not need to be fixed on the porous chuck table 15.

As illustrated in FIG. 6D, the light transmissive substrate 10 is diced by half-cut dicing with a dicing device between the spacers 5 on the surface of the light transmissive substrate 10 on which the spacers 5 are formed, thereby forming ditches 11 (step S3A).

The light transmissive substrate 10 has been bonded to the support 12, so that it is not curved even after the ditches 11 are formed and it can be effectively transported. Furthermore, the protective tape 14 keeps clean the surface of the light transmissive substrate 10.

As illustrated in FIG. 6E, the light transmissive substrate 10, to which the support 12 is bonded, is bonded to the solid-state imaging element wafer 20 (step S4A).

As illustrated in FIG. 6F, the support 12 bonded to the light transmissive substrate 10 is heated or irradiated with ultraviolet rays to self-peel the self-peeling double-face tape 13, resulting in peeling of the support 12 from the light transmissive substrate 10 (step S5A).

As illustrated in FIG. 6G, the protective tape 14 is peeled from the light transmissive substrate 10 (step S6A).

As illustrated in FIG. 6H, the light transmissive substrate 10 is diced into an individual cover glass 4 (step S7A).

After the light transmissive substrate 10 has been diced, the solid-state imaging element wafer 20 is diced into an individual solid-state imaging element chip 2 to produce the solid-state imaging device 1 (step S8A).

### Example

A specific example of a method of producing the solid-state imaging device according to the present invention is described below. The reference numbers appearing hereunder use those shown in FIGS. 1, 2, 4 and 6.

An eight inch and 300 μm thick Pyrex (registered trademark) glass was used as the light transmissive substrate 10. A 50 μm high spacer 5 was formed on the light transmissive substrate 10.

A half-cut dicing was performed between the spacers 5 with a depth of 150 μm and 80 lines in the vertical and the horizontal direction. A dicing device produced by DISCO Corporation was used for dicing. A “UHP-1005M3 (ultraviolet-rays peeling model)” produced by DENKI KAGAKU KOGYO KABUSHIKI KAISHA was used as the dicing tape. A resin bond grinding stone with an outer diameter of 55 mm, a width of 0.1 mm to 0.7 mm and a grain size of #400 was used. The number of revolutions of the grinding stone was 30000 rpm and a processing speed was 1 mm/sec to 2 mm/sec.

The light transmissive substrate 10 in which the ditches 11 were formed under these conditions was sucked by the porous chuck table 15 with a flatness of ±5 μm or less to prevent breakdown, thereby peeling the dicing tape.

After the dicing tape was peeled, an eight inch and 500 μm thick Pyrex glass as the support 12 was bonded to the light transmissive substrate 10. At the time of bonding, “SELFA BG” produced by Sekisui Chemical Co., Ltd. which is an ultraviolet self-peeling double-face tape or “RIBA-ALPHA 3195” produced by Nitto Denko Corporation which is thermal self-peeling double-face tape and is peeled at a temperature of 90° C. was stuck on the support 12 as self-peeling double-face tape 13. At the time of sticking, a rubber roller was used to eject bubbles and a general adhesive surface was stuck on the support 12.

After the self-peeling double-face tape 13 was stuck on the support 12, the substrate surface of the protective tape 14 was stuck on the self-peeling surface of the self-peeling double-face tape 13. An “ELEP HOLDER ELP UB-3083D” produced by Nitto Denko Corporation was used as the protective tape 14. A rubber roller was used at the time of sticking.

The support 12, the self-peeling double-face tape 13 and the protective tape 14 were stacked one on top of another in that manner are bonded under vacuum of 3 torr (about 400 Pa) to avoid trapped bubbles. The support 12 was bonded and then the light transmissive substrate 10 was bonded to the solid-state imaging element wafer 20 on which a large number of the solid-state imaging elements 3 was formed. A 10 mm diameter opening was provided in the self-peeling double-face tape and the protective tape 14 correspondingly to the position of an alignment mark so that the alignment mark on the solid-state imaging element wafer 20 was able to be confirmed.

At that point, it was confirmed that the stiffness of the light transmissive substrate 10 was maintained by the support 12 and the light transmissive substrate 10 could be transported and bonded without any problem.

In the case that “SELFA BG” was used as the self-peeling double-face tape 13 to peel the support 12, “SELFA BG” was radiated with ultraviolet rays with a illuminance of 30 mW/cm² from the side of the support 12 for three minutes to cause it to produce self-peeling property. It was thereby confirmed that the adhesive force of the self-peeling double-face tape 13 was reduced to easily peel the support 12 and the self-peeling double-face tape 13 was also peeled along with the support 12 because a general adhesive surface was not lowered in adhesive force.

In the case that “RIBA-ALPHA 3195” was used as the self-peeling double-face tape 13, all of the bonded solid-state imaging element wafer 20, the light transmissive substrate 10 and the support 12 were put into an oven heated to a temperature of 100° C. and heated for two minutes. It was thereby confirmed that the adhesive force of the self-peeling double-face tape 13 was lowered to easily peel the support 12 and the self-peeling double-face tape 13 was also peeled along with the support 12 because a general adhesive surface was not lowered in adhesive force.

After that, the protective tape 14 was peeled from the light transmissive substrate 10 and the surface thereof was checked. As a result, it was confirmed that no dirt and foreign substance having a size over 1 μm stuck to the surface to maintain good cleanness.

As described above, according to the method of producing the solid-state imaging device of the present invention, the stiffness of the light transmissive substrate in which ditches are formed by half-cut dicing is increased by the support to prevent the light transmissive substrate from being curved, improve transportability and avoid damage. In addition, the protective tape keeps clean the surface of the light transmissive substrate.

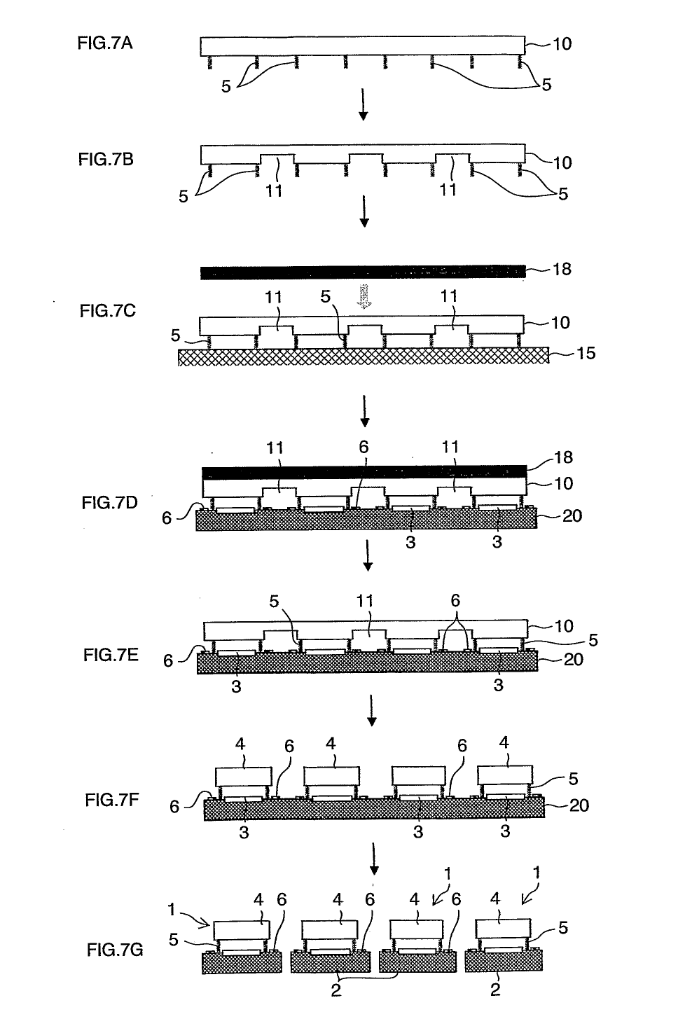

Although the sheet material such as Pyrex glass was used as the support 12 in the embodiment of the present invention, the present invention is not limited to the Pyrex glass, but can be preferably embodied with use of a tape material which leaves little adhesive residue and is thick in substrate portion like the protective tape 18 illustrated in FIG. 7C.

Specifically, a back grinding protective tape “SP5013B-260 (ultraviolet-rays peeling model)” produced by THE FURUKAWA ELECTRIC CO., LTD. of which the substrate portion is 200 μm or more in thickness and is adapted for a thin wafer was used as the protective tape 18, stuck to the light transmissive substrate 10 fixed on the porous chuck table 15 as illustrated in FIG. 7C, transported as in the case of the foregoing example and bonded to the solid-state imaging element wafer 20.

As the result, it was confirmed that the stiffness of the light transmissive substrate was maintained and the light transmissive substrate could be transported and bonded without any problem.

1. A method of producing a solid-state imaging device such that a solid-state imaging element wafer is bonded to a light transmissive substrate on one surface of which spacers are formed so as to surround solid-state imaging elements formed on the solid-state imaging element wafer and ditches are formed between the spacers to produce a bonded substrate and then the bonded substrate is divided correspondingly to the individual solid-state imaging elements, the method of producing the solid-state imaging device characterized by comprising the step of:
bonding a support to a surface opposite to the surface of the light transmissive substrate on which the ditches are formed.

2. The method of producing the solid-state imaging device according to claim 1, wherein
the support is bonded to the light transmissive substrate by a self-peeling double-face tape of which at least one face is self-peeled by heating or radiating with ultraviolet rays.

3. The method of producing the solid-state imaging device according to claim 1, wherein
a protective tape which protects the surface of the light transmissive substrate is stuck on the surface opposite to the surface of the light transmissive substrate on which the ditches are formed and the self-peeling double-face tape is stuck on the protective tape.

4. The method of producing the solid-state imaging device according to any claim 1, wherein
the support is a sheet material formed of glass, resin or metal.

5. The method of producing the solid-state imaging device according to claim 1, wherein
the support is formed of a sheet material with light transmissivity in the case where the self-peeling double-face tape is self-peeled by ultraviolet rays.

6. The method of producing the solid-state imaging device according to claim 1, wherein
in the case where the self-peeling double-face tape is heated to be self-peeled, the self-peeling double-face tape is heated at a temperature lower than a temperature at which the spacer is peeled from the solid-state imaging element wafer or the light transmissive substrate or the spacer is fractured due to a warp caused by difference in thennal expansion coefficient between the solid-state imaging element wafer and the light transmissive substrate.

7. The method of producing the solid-state imaging device according to claim 1, wherein
an opening through which the solid-state imaging element wafer can be imaged is provided in the self-peeling double-face tape and the protective tape.

8. The method of producing the solid-state imaging device according to claim 2, wherein
a protective tape which protects the surface of the light transmissive substrate is stuck on the surface opposite to the surface of the light transmissive substrate on which the ditches are formed and the self-peeling double-face tape is stuck on the protective tape.

9. The method of producing the solid-state imaging device according to claim 8, wherein
the support is a sheet material formed of glass, resin or metal.

10. The method of producing the solid-state imaging device according to claim 9, wherein
the support is formed of a sheet material with light transmissivity in the case where the self-peeling double-face tape is self-peeled by ultraviolet rays.

11. The method of producing the solid-state imaging device according to claim 10, wherein
in the case where the self-peeling double-face tape is heated to be self-peeled, the self-peeling double-face tape is heated at a temperature lower than a temperature at which the spacer is peeled from the solid-state imaging element wafer or the light transmissive substrate or the spacer is fractured due to a warp caused by difference in thermal expansion coefficient between the solid-state imaging element wafer and the light transmissive substrate.

12. The method of producing the solid-state imaging device according to claim 11, wherein
an opening through which the solid-state imaging element wafer can be imaged is provided in the self-peeling double-face tape and the protective tape.
